(19) United States
(12) Patent Application Publication
(10) Pub. No.: US 2011/0149496 A1
(43) Pub. Date: Jun. 23, 2011

(54) COMPUTER SYSTEM EMPLOYING LIGHT-GUIDING MEMBER

(75) Inventor: CHOON-TYNG LAU, Tu-Cheng (TW)

(73) Assignee: HON HAI PRECISION INDUSTRY CO., LTD., Tu-Cheng (TW)

(21) Appl. No.: 12/770,785

(22) Filed: Apr. 30, 2010

(30) Foreign Application Priority Data
Dec. 18, 2009 (CN) 200910311802.3

(51) Int. Cl. H05K 7/00

(52) U.S. Cl. 361/679.09

(57) ABSTRACT

A computer system includes a chassis, a keyboard, a light-emitting member, a light-guiding member, and a control system. The keyboard is attached to the chassis. The light-emitting member is disposed in the chassis and capable of emitting light. The light-guiding member directs light of the light-emitting member to irradiate on the keyboard. The control system is electronically coupled to the light-emitting member to control light brightness of the light-emitting member.

### BACKGROUND

1. Technical Field

The present disclosure relates to a computer system with a light-guiding member.

2. Description of Related Art

It is very difficult to operate a keyboard of a computer in the dark. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a computer system in accordance with an embodiment.

FIG. 2 is an exploded view of an embodiment of a chassis of the computer system of FIG. 1.

FIG. 3 is a block diagram of a computer system, a control system, and a light-emitting member in accordance with an embodiment.

FIG. 4 is a block diagram of an alternative embodiment of a control system and a light-emitting member.

FIG. 5 is a block diagram of another alternative embodiment of a control system and a light-emitting member.

FIG. 6 is a block diagram of yet another alternative embodiment of a control system and a light-emitting member.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

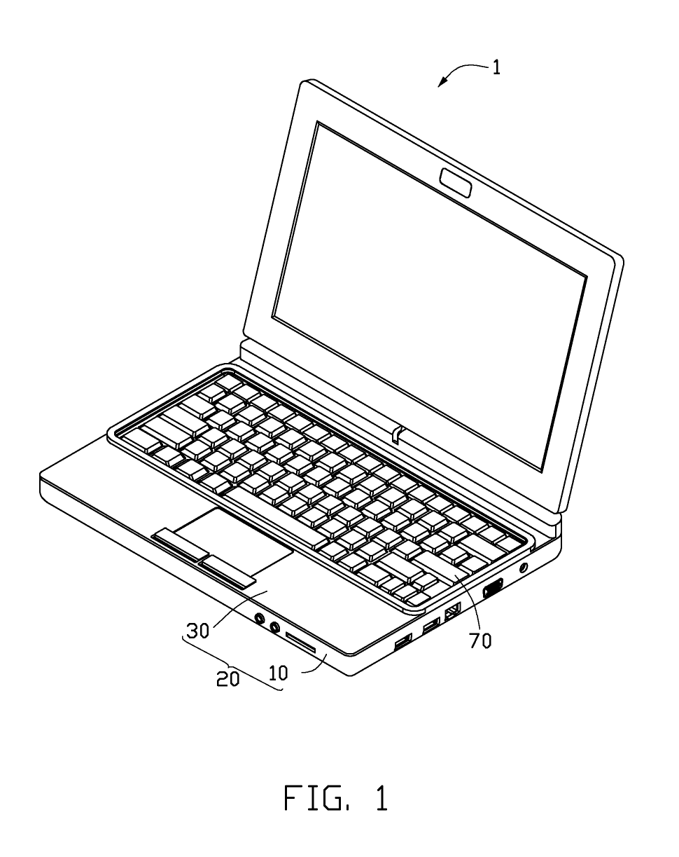

Referring to FIG. 1, a computer system 1 in accordance with an embodiment includes a chassis 20. The chassis 20 includes a base 10 and a top cover 30 secured to the base 10. A keyboard 70 is located on the top cover 30.

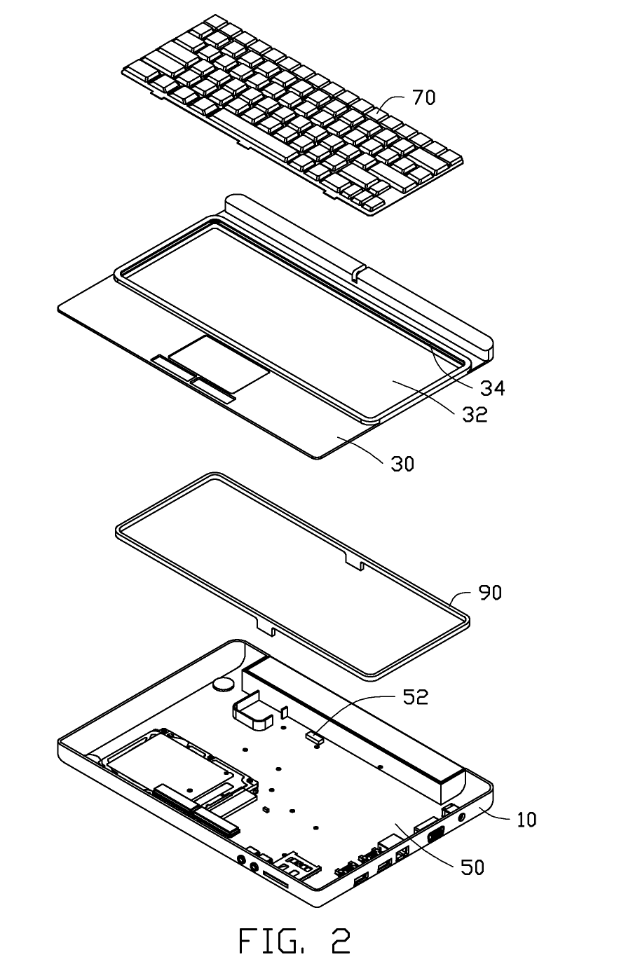

Referring to FIG. 2, the base 10 receives a motherboard 50. A light-emitting member 52, such as a light-emitting diode, is disposed in the chassis 20. In an exemplary embodiment, the light-emitting member 52 is disposed on the motherboard 50.

The top cover 30 defines a recess 32 to receive the keyboard 70. A gap 34 is defined in the recess 32. A light-guiding member 90 is located below the top cover 30 framing the recess 32.

In assembly, the light-guiding member 90 is located on the light-emitting member 52 of the motherboard 50. The keyboard 70 is received in the recess of the top cover 30. The top cover 30 is secured to the base 10, and the light-guiding member 90 frames the recess 32.

In use, when the light-emitting member 52 emits light to the light-guiding member 90, the light spreads throughout the light-guiding member 90 to light up the keyboard 70 through the gap 34. Therefore, the keys of the keyboard 70 are visible in the dark when the computer system 1 is on.

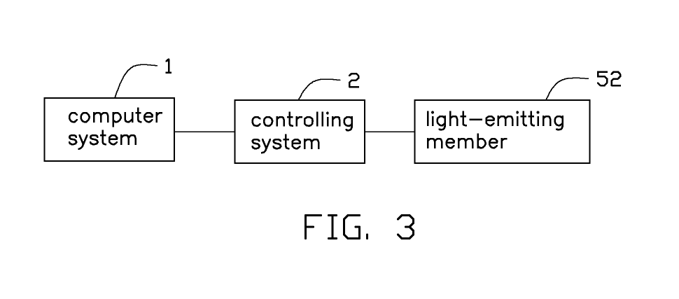

Referring to FIG. 3, in an exemplary embodiment, brightness of light emitted by the light-emitting member 52 can be controlled by a control system 2.

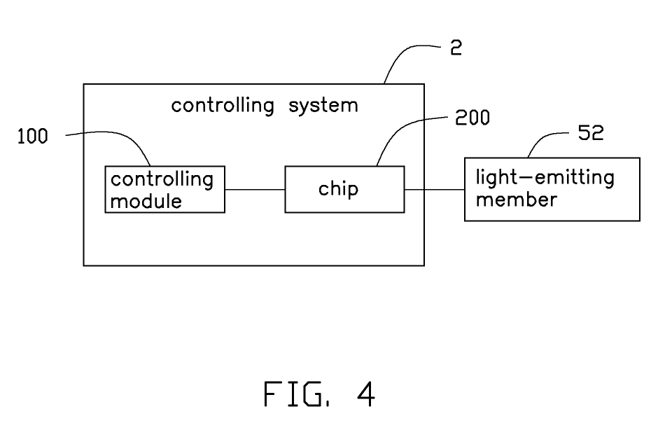

Referring to FIG. 4, in an alternative exemplary embodiment, the control system 2 includes a control module 100 and a chip 200. The control module 100 is electronically coupled to the light-emitting member 52 via the chip 200. Signals sent to the chip 200 from the control module 100 can turn the light-emitting member 52 on and off and control brightness of the light when it is on. For example, when the chip 200 receives the signal, a suitable work voltage is provided to the light-emitting member 52, for example, via lead of the chip 200, to have the light-emitting member 52 emitting light. If the light-emitting member 52 is desired to be turned off, another signal is sent to the chip 200 from the control module 100. When the chip 200 receives another signal, the suitable work voltage is switch off and the light-emitting member 52 is turned off.

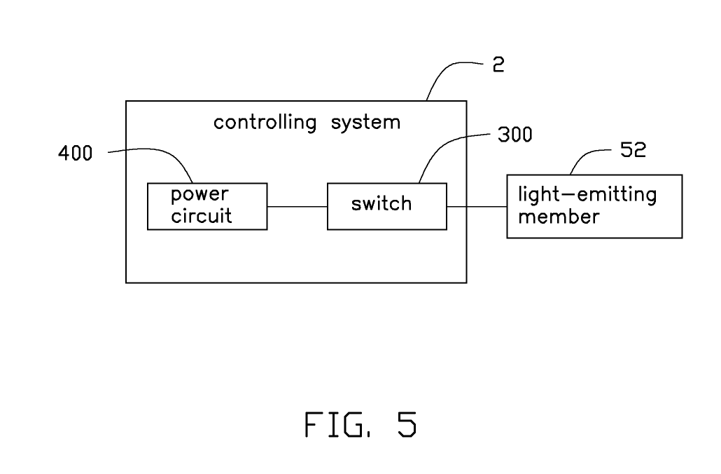

Referring to FIG. 5, in another alternative exemplary embodiment, the control system 2 includes a power circuit 400 and a switch 300. The light-emitting member 52 is electronically coupled to the power circuit 400 via the switch 300. The power circuit 400 is capable of providing a suitable work voltage to the light-emitting member 52 when the switch 300 is switched on.

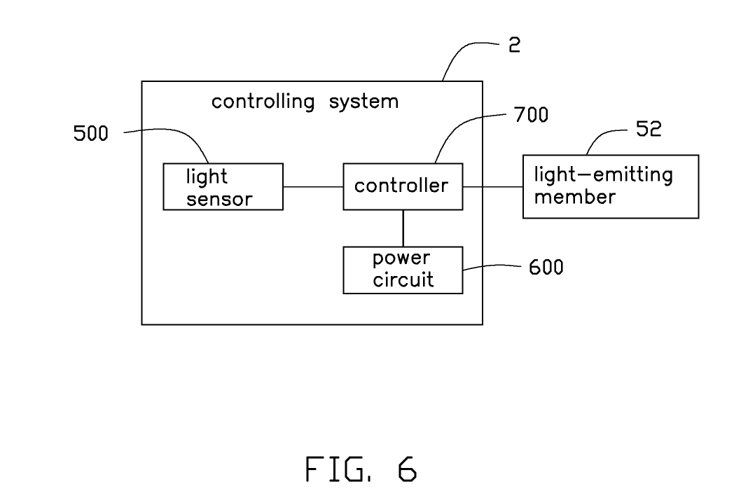

Referring to FIG. 6, in yet another alternative exemplary embodiment, the control system 2 includes a light sensor 500, a power circuit 600, and a controller 700. The light-emitting member 52 is electronically coupled to the light sensor 500 and the power circuit 600 via the controller 700. The power circuit 600 is capable of providing a suitable work voltage to the light-emitting member 52 via the controller 700. The light sensor 500 is capable of detecting brightness of ambient light in vicinity of the light sensor 500 and sending the detected brightness to the controller 700. One or more predefined brightness values associated with control commands are stored in the controller 700. The controller 700 controls amount of power to the light-emitting member 52 from the power circuit 600 according to detected brightness of ambient light and the associated command. If ambient light is low, for example, 50% power could be sent to the light-emitting member 52 to provide some light for a user. If it is detected that ambient light is very low, then 100% power could be provided so that maximum brightness of the light-emitting member 52 is provided for the user.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A computer system comprising:
a chassis;
a keyboard attached to the chassis;
a light-emitting member disposed in the chassis and capable of emitting light;
a light-guiding member directing light of the light-emitting member to irradiate on the keyboard; and
a control system electronically coupled to the light-emitting member to control light brightness of the light-emitting member.

2. The computer system of claim 1, wherein the light-guiding member surrounds the keyboard.

3. The computer system of claim 1, wherein the chassis comprises a top cover; the top cover defines a recess that receives the keyboard.

4. The computer system of claim 3, wherein the recess defines a gap to allow the light directed by the light-guiding member to irradiate on the keyboard.

5. The computer system of claim 4, wherein the chassis further comprises a base; the top cover is secured to the base; a motherboard is located in the base; and the light-emitting member is electronically connected to the motherboard.

6. The computer system of claim 1, wherein the control system comprises a control module and a chip; and the light-emitting member electronically coupled to the control module via the chip.

7. The computer system of claim 6, wherein the control module sends a signal to the chip to provide a suitable work voltage to the light-emitting member to enable the light-emitting member to emit light and sends another signal to the chip to stop the light-emitting member from emitting light.

8. The computer system of claim 1, wherein the control system comprises a power circuit and a switch; the light-emitting member is electronically coupled to the power circuit via the switch; and the switch can switch on or off the light-emitting member.

9. The computer system of claim 1, wherein the control module comprises a light sensor, a controller and a power circuit; and the light-emitting member is electronically coupled to the light sensor and the power circuit respectively.

10. The computer system of claim 9, wherein the light sensor is capable of detecting brightness of ambient light; the power circuit is capable of providing a suitable work voltage to the light emitting member; and the controller stores one or more predefined brightness values associated with control commands and controls amount of power to the light-emitting member from the power circuit according to the detected brightness of ambient light and the associated command.

11. A computer system comprising:
a chassis defining a gap;
a keyboard attached to the chassis;
a light-emitting member disposed in the chassis and capable of emitting light; and
a light-guiding member disposed in the chassis, to direct light of the light-emitting member through the gap to irradiate on the keyboard.

12. The computer system of claim 11, further comprising a control system electronically coupled to the light-emitting member to control light brightness of the light-emitting member.

13. The computer system of claim 11, wherein the light-guiding member surrounds the keyboard.

14. The computer system of claim 12, wherein the chassis comprises a top cover; the top cover defines a recess that receives the keyboard.

15. The computer system of claim 14, wherein the chassis further comprises a base; the top cover is secured to the base; a motherboard is located in the base; and the light-emitting member is electronically connected to the motherboard.

16. The computer system of claim 12, wherein the control system comprises a control module and a chip; and the light-emitting member electronically coupled to the control module via the chip.

17. The computer system of claim 16, wherein the control module sends a signal to the chip to provide a suitable work voltage to the light-emitting member to enable the light-emitting member to emit light and sends another signal to the chip to stop the light-emitting member from emitting light.

18. The computer system of claim 12, wherein the control system comprises a power circuit and a switch; the light-emitting member is electronically coupled to the power circuit via the switch; and the switch can switch on or off the light-emitting member.

19. The computer system of claim 12, wherein the control module comprises a light sensor, a controller and a power circuit; and the light-emitting member is electronically coupled to the light sensor and the power circuit respectively.

20. The computer system of claim 19, wherein the light sensor is capable of detecting brightness of ambient light; the power circuit is capable of providing a suitable work voltage to the light emitting member; and the controller stores one or more predefined brightness values associated with control commands and controls amount of power to the light-emitting member from the power circuit according to the detected brightness of ambient light and the associated command.
